(19) United States
(12) Patent Application Publication
(10) Pub. No.: US 2024/0335958 A1
(43) Pub. Date: Oct. 10, 2024

(54) AUTOMATIC CHIP PICK-AND-PLACE APPARATUS AND FORMATION METHOD THEREOF

(71) Applicant: SEMIGHT INSTRUMENTS CO., LTD, Suzhou (CN)

(72) Inventors: Shan ZHAO, Suzhou (CN); Zhe LIAN, Suzhou (CN); Yonghong WU, Suzhou (CN); Jianjun HUANG, Suzhou (CN)

(21) Appl. No.: 18/433,771

(22) Filed: Feb. 6, 2024

Related U.S. Application Data
(63) Continuation of application No. PCT/CN2023/134152, filed on Nov. 24, 2023.

(30) Foreign Application Priority Data
Apr. 6, 2023 (CN) 202320742516.8

(51) Int. Cl. B25J 15/06; H01L 21/67

(52) U.S. Cl. CPC B25J 15/0616; H01L 21/67144

(57) ABSTRACT

The present disclosure provides an automatic die pick-and-place apparatus and a formation method. The apparatus includes a main body; a suction nozzle rod installed on the main body; a clamping strip disposed above the main body, where a front end of the clamping strip extends outward from the main body; and a guiding assembly disposed on a front end surface of the main body and on two sides of the suction nozzle rod. The first spring is vertically disposed and connected between the clamping strip and a lower portion of the main body; an installation groove is formed on the front end surface of the main body; a magnetic block is inserted in the installation groove; a magnetic installation block is sleeved on the suction nozzle rod and attracted to be connected to the magnetic block; and a limiting block is installed on a front portion of the main body.

### CROSS-REFERENCE TO RELATED APPLICATION

This application is a continuation application of PCT/CN2023/134152, filed on Nov. 24, 2023, which claims the priority of Chinese Patent Application No. 202320742516.8, filed on Apr. 6, 2023, the entirety of all of which is incorporated herein by reference.

### TECHNICAL FIELD

The present disclosure generally relates to the field of semiconductor die mounting and testing technology and, more particularly, relates to an automatic die pick-and-place apparatus and a formation method thereof.

### BACKGROUND

In die manufacturing and using processes of semiconductor industry, die testing and mounting are essential necessary processes. In the testing and mounting processes, transportation and high-precision placement of dies are needed, which may require the usage of mounting apparatuses and testing apparatuses (e.g., machines). As a part in the testing apparatus or the mounting apparatus that is in a direct contact with the die, a die pick-and-place apparatus plays an important role in the testing apparatus or the mounting apparatus. In the testing and mounting processes of optical communication industry, high requirements are needed for both die pick-and-place precision and a contact pressure between a suction nozzle and the die due to process needs. During long-term usage, a suction nozzle rod needs to be wiped to remove dust particles accumulated on surface. However, external wiping force may cause the suction nozzle rod to shift or even fall off.

### SUMMARY

One aspect of the present disclosure provides an automatic die pick-and-place apparatus. The automatic die pick-and-place apparatus includes a main body; a suction nozzle rod installed on the main body; a clamping strip disposed above the main body, where a front end of the clamping strip extends outward from the main body and is clamped to be connected with an upper end of the suction nozzle rod; and a guiding assembly disposed on a front end surface of the main body and on two sides of the suction nozzle rod. The first spring is vertically disposed and connected between the clamping strip and a lower portion of the main body; an installation groove is formed on the front end surface of the main body; a magnetic block is inserted in the installation groove; a magnetic installation block is sleeved on the suction nozzle rod and attracted to be connected to the magnetic block; and a limiting block is installed on a front portion of the main body; a main body portion of the limiting block is connected to the main body; a limiting portion of the limiting block is at an outer side of a front end of the main body; and a guiding groove for the suction nozzle rod to be inserted is formed at a surface of the limiting portion facing toward the main body.

Optionally, the main body portion of the limiting block is connected to a left side surface or a right side surface of the main body through one or more bolts.

Optionally, the limiting block is an L-shaped limiting block.

Optionally, an avoiding opening matched with the magnetic installation block is formed at the limiting portion of the limiting block.

Optionally, the guiding assembly is distributed above and/or below the limiting portion.

Optionally, the installation groove is formed at a central region of the front end surface of the main body.

Optionally, a surface of the magnetic block is coplanar with the front end surface of the main body.

Optionally, the magnetic installation block is fixedly installed at a middle region of the suction nozzle rod.

Optionally, a clamping screw is disposed at the front end of the clamping strip; and an upper end of the first spring is connected to the clamping screw.

Another aspect of the present disclosure provides an automatic die pick-and-place apparatus. The automatic die pick-and-place apparatus include a main body; a suction nozzle rod installed on the main body; a clamping strip disposed above the main body, where a front end of the clamping strip extends outward from the main body and is clamped to be connected with an upper end of the suction nozzle rod; and a guiding assembly, including at least two pairs of bearings and disposed on a front end surface of the main body and on two sides of the suction nozzle rod. A first spring is vertically disposed and connected between the clamping strip and a lower portion of the main body; an installation groove is formed on the front end surface of the main body; a magnetic block is inserted in the installation groove; and a magnetic installation block is sleeved on the suction nozzle rod and attracted to be connected to the magnetic block.

Optionally, the automatic die pick-and-place apparatus further includes a limiting block installed on a front portion of the main body, where a main body portion of the limiting block is connected to the main body; a limiting portion of the limiting block is at an outer side of a front end of the main body; and a guiding groove for the suction nozzle rod to be inserted is formed at a surface of the limiting portion facing toward the main body.

Optionally, the front end surface of the main body includes at least two protruding blocks configured to be spaced apart along a vertical direction.

Optionally, a pair of bearings is installed on a protruding block.

Optionally, in each pair of bearings, a left bearing is installed horizontally on a left side of the protruding block, and a right bearing is installed horizontally on a right side of the protruding block.

Optionally, a clamping channel is formed between the left bearing and the right bearing in each pair of bearings.

Optionally, the suction nozzle rod is in the clamping channel.

Optionally, the guiding assembly is distributed above and/or below the limiting portion.

Optionally, the installation groove is formed at a central region of the front end surface of the main body.

Optionally, a surface of the magnetic block is coplanar with the front end surface of the main body.

Another aspect of the present disclosure provides a formation method of an automatic die pick-and-place apparatus. The method includes providing a main body; installing a suction nozzle rod on the main body; disposing a clamping strip above the main body, where a front end of the clamping strip extends outward from the main body and is clamped to be connected with an upper end of the suction nozzle rod; and disposing a guiding assembly on a front end surface of the main body and on two sides of the suction nozzle rod. A first spring is vertically disposed and connected between the clamping strip and a lower portion of the main body; an installation groove is formed on the front end surface of the main body; a magnetic block is inserted in the installation groove; a magnetic installation block is sleeved on the suction nozzle rod and attracted to be connected to the magnetic block; and a limiting block is installed on a front portion of the main body; a main body portion of the limiting block is connected to the main body; a limiting portion of the limiting block is at an outer side of a front end of the main body; and a guiding groove for the suction nozzle rod to be inserted is formed at a surface of the limiting portion facing toward the main body.

Other aspects of the present disclosure may be understood by those skilled in the art in light of the description, the claims, and the drawings of the present disclosure.

### BRIEF DESCRIPTION OF THE DRAWINGS

Accompanying drawings, which are incorporated into a part of the present disclosure, illustrate embodiments of the present disclosure and together with the specification to explain the principle of the present disclosure. With reference to accompanying drawings, some specific embodiments of the present disclosure are described in detail below through a manner of illustration and not-limitation. Same reference numbers in accompanying drawings means same or similar parts or portions. Those skilled in the art should understand that accompanying drawings are not necessarily drawn according to scale.

FIG. 1 illustrates a structural schematic of an automatic die pick-and-place apparatus in a usage scenario according to various embodiments of the present disclosure.

FIG. 2 illustrates a structural schematic of an automatic die pick-and-place apparatus according to various embodiments of the present disclosure.

FIG. 3 illustrates a partial structural schematic of an automatic die pick-and-place apparatus according to various embodiments of the present disclosure.

FIG. 4 illustrates a structural schematic of a guiding assembly of an automatic die pick-and-place apparatus according to various embodiments of the present disclosure.

FIG. 5A illustrates a structural schematic of an exemplary die testing apparatus.

FIG. 5B illustrates a structural block diagram of the exemplary die testing apparatus in FIG. 5A.

FIG. 6 illustrates a structural schematic of a die testing region of an exemplary die testing apparatus.

FIG. 7 illustrates a flowchart of a formation method of an automatic die pick-and-place apparatus according to various embodiments of the present disclosure.

### DETAILED DESCRIPTION

Various exemplary embodiments of the present disclosure are described in detail with reference to accompanying drawings. It should be noted that unless stated otherwise, relative arrangement of assemblies and steps, numerical expressions and values described in those embodiments may not limit the scope of the present disclosure.

Following description of at least one exemplary embodiment may be merely illustrative and may not be configured to limit the present disclosure and its application or use.

The technologies, methods and apparatuses known to those skilled in the art may not be discussed in detail, but where appropriate, the technologies, methods and apparatuses should be considered as a part of the present disclosure.

In all examples shown and discussed herein, any specific value should be interpreted as merely exemplary, rather than as a limitation. Therefore, other examples in exemplary embodiment may have different values.

It is apparent to those skilled in the art that various modifications and variations may be made in the present disclosure without departing from the spirit or scope of the present disclosure. Therefore, the present disclosure is intended to cover modifications and variations of the present disclosure falling within the scope of corresponding claims (technical solutions to be protected) and their equivalents. It should be noted that, implementation manners provided in embodiment of the present disclosure may be combined with each other if there is no contradiction.

It should be noted that similar reference numerals and letters are configured to indicate similar items in following drawings. Therefore, once an item is defined in one drawing, it does not need to be further discussed in subsequent drawings.

The present disclosure may be further clearly understood through the specific examples given below, which may not limited the present disclosure.

A known good die (KGD) is defined as a package type fully supported by suppliers to meet or exceed quality, reliability, and functional data sheet specifications, with non-standardized (die specific) but completely and electronically transferable mechanical specifications. A KGD (known good die) testing apparatus (e.g., KGD testing apparatus, KGD tester, KGD testing equipment, or KGD test cell) is configured for the die testing before packaging and after splitting. The die testing apparatus confirms that dies with desirable performance are used for packaging before high-density packaging, which improves the cumulative packaging yield. The die testing apparatus may realize a fully automatic testing system and automatically realize picking, transporting, testing and unloading of dies. The die testing apparatus may support multi-station parallel testing. Different stations may support different temperatures and test projects. Different stations may support static, dynamic, and avalanche function tests; and the test sequence may be adjustable. The die testing apparatus may support high temperature testing with a temperature range from room temperature to 200° C. The power-on pin card may be a sealed design, support nitrogen filling protection against high-pressure sparking and nitrogen pressure monitoring and support high-temperature preheating and die surface anti-oxidation protection. It should be noted that “die” and “chip” may be interchangeable in the present disclosure, which may not be limited according to various embodiments of the present disclosure.

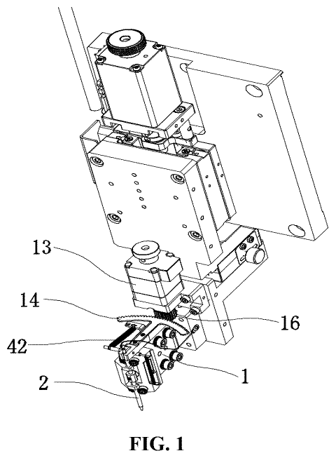

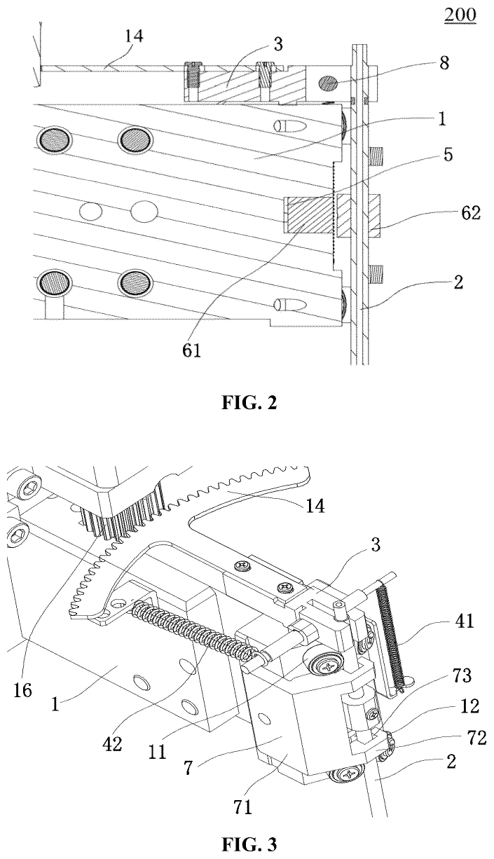

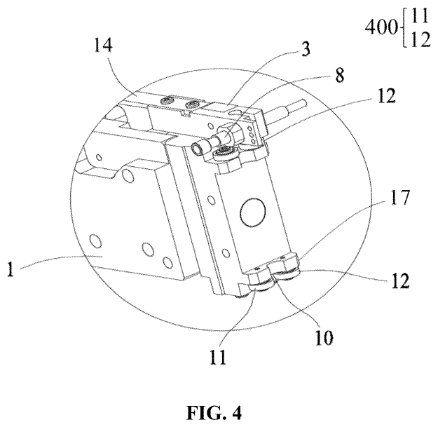

Exemplary embodiments are described in the present disclosure with reference to FIGS. 1-4, which are schematics used for describing various, different embodiments. Referring to FIGS. 1-4, FIG. 1 illustrates a structural schematic of an automatic die pick-and-place apparatus in a usage scenario according to various embodiments of the present disclosure; FIG. 2 illustrates a structural schematic of the automatic die pick-and-place apparatus according to various embodiments of the present disclosure; FIG. 3 illustrates a partial structural schematic of the automatic die pick-and-place apparatus according to various embodiments of the present disclosure; and FIG. 4 illustrates a structural schematic of a guiding assembly of the automatic die pick-and-place apparatus according to various embodiments of the present disclosure.

### Exemplary Embodiment One

The present disclosure provides an automatic die pick-and-place apparatus. An automatic die pick-and-place apparatus 200 may include a main body 1 and a suction nozzle rod 2 installed on the main body 1; a clamping strip 3 disposed above the main body 1, where the front end of the clamping strip 3 extends outward from the main body 1 and is clamped to be connected with the upper end of the suction nozzle rod 2; and further include a guiding assembly 400 disposed on the front end surface of the main body 1 and on two sides of the suction nozzle rod 2. A first spring 41 may be vertically arranged and connected between the clamping strip 3 and the lower portion of the main body 1. An installation groove 5 may be formed on the front end surface of the main body 1. A magnetic block 61 may be inserted in the installation groove 5. The magnetic installation block 62 may be sleeved on the suction nozzle rod 2 and attracted to be connected to the magnetic block 61, which may ensure the freedom of the suction nozzle rod along the vertical direction and facilitate disassembly and assembly of the suction nozzle rod.

In one embodiment, a limiting block 7 may be installed on the front portion of the main body 1. A main body portion 71 of the limiting block 7 may be connected to the main body 1. A limiting portion 72 of the limiting block 7 may be at an outer side of the front end of the main body 1; and a guiding groove 73 for the suction nozzle rod 2 to be inserted may be formed at the surface of the limiting portion 72 facing toward the main body 1, which may prevent the suction nozzle rod 1 from falling off due to external force when the suction nozzle rod 1 is wiped.

In one embodiment, the main body portion 71 of the limiting block 7 may be connected to the left side surface of the main body 1 through bolts. Above-mentioned limiting block 7 may be an L-shaped limiting block. An avoiding opening matched with the magnetic installation block 62 may be formed at the limiting portion 72 of the limiting block 71. A clamping screw 8 may be disposed at the front end of the clamping strip 3, and the upper end of the first spring 41 may be connected to the clamping screw 8.

In one embodiment, the rear end portion of above-mentioned clamping strip 3 may be connected to an arc-shaped rack 14. The arc-shaped rack 14 may be meshed with a gear 16 installed on an output axle of a motor 13; and the center of the arc-shaped rack 14 may be overlapped with the axis center of the suction nozzle rod 2. A second spring 42 disposed obliquely to the horizontal direction may be connected between the clamping strip 3 and the upper portion of the main body 1. One end of the second spring 42 may be adjacent to the arc-shaped rack 14 and below the arc-shaped rack 14, and another end of the second spring 42 may be connected to an end of the clamping strip 3 away from the arc-shaped rack 14.

### Exemplary Embodiment Two

The present disclosure provides an automatic die pick-and-place apparatus. The automatic die pick-and-place apparatus 200 may include the main body 1 and the suction nozzle rod 2 installed on the main body 1; the clamping strip 3 disposed above the main body 1, where the front end of the clamping strip 3 extends outward from the main body 1 and is clamped to be connected with the upper end of the suction nozzle rod 2; and further include the guiding assembly 400 disposed on the front end surface of the main body 1 and on two sides of the suction nozzle rod 2. The first spring 41 may be vertically arranged and connected between the clamping strip 3 and the lower portion of the main body 1. The installation groove 5 may be formed on the front end surface of the main body 1. The magnetic block 61 may be inserted in the installation groove 5. The magnetic installation block 62 may be sleeved on the suction nozzle rod 2 and attracted to be connected to the magnetic block 61. The automatic die pick-and-place apparatus 200 may further include the limiting block 7 installed on the front portion of the main body 1. The main body portion 71 of the limiting block 7 may be connected to the main body 1. The limiting portion 72 of the limiting block 7 may be at an outer side of the front end of the main body 1; and the guiding groove 73 for the suction nozzle rod 2 to be inserted may be formed at the surface of the limiting portion 72 facing toward the main body 1.

In one embodiment, the guiding assembly 400 may include at least two pairs of bearings (e.g., the left bearing 11 and the right bearing 12). The front end surface of above-mentioned main body 1 may include at least two protruding blocks 17 configured to be spaced apart along the vertical direction. A pair of bearings may be installed on each above-mentioned protruding block 17. In each pair of bearings, the left bearing 11 may be installed horizontally on the left side of the protruding block 17, and the right bearing 12 may be installed horizontally on the right side of the protruding block 17. A clamping channel 10 may be formed between the left bearing 11 and the right bearing 12 in each pair of bearings, and above-mentioned suction nozzle rod 2 may be in the clamping channel 10. Above-mentioned guiding assembly 400 may be distributed above and below the limiting portion 72. Above-mentioned installation groove 5 may be formed in the central region of the front end surface of the main body 1. The surface of above-mentioned magnetic block 61 may be coplanar with the front end surface of the main body 1. Above-mentioned magnetic installation block 62 may be fixedly installed in the middle portion of the suction nozzle rod 2.

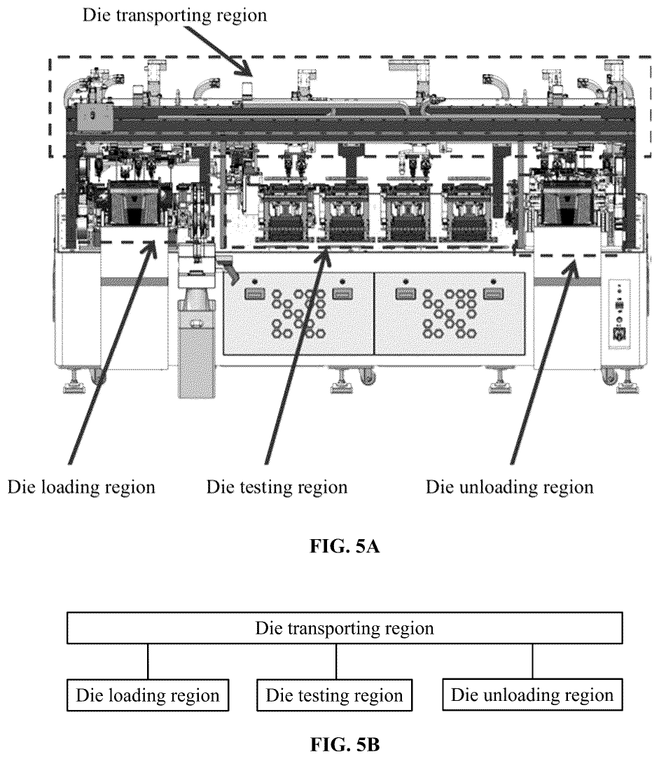

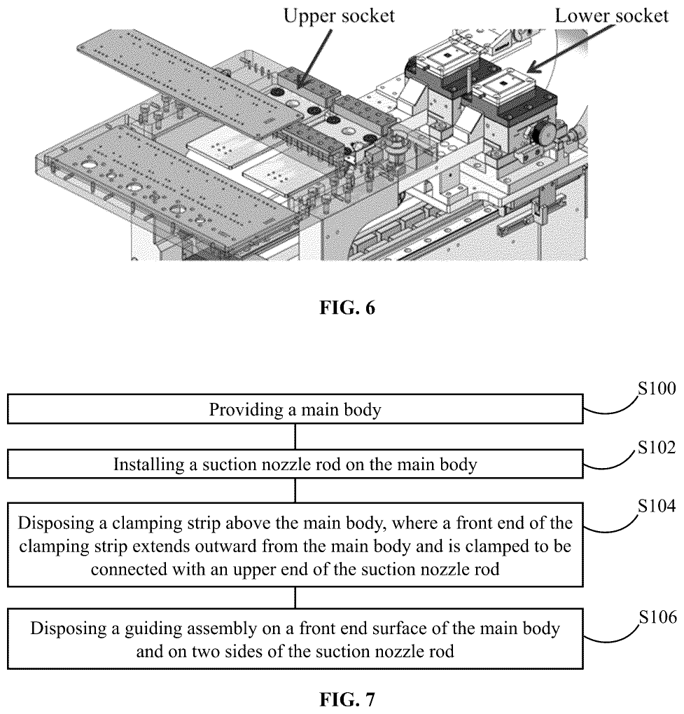

The main structure of the die testing apparatus may include four parts, that is, a die automatic loading region, a die transporting region, a die testing region and a die unloading region, as shown in FIGS. 5A-5B. Referring to FIGS. 5A-5B and 6, FIG. 5A illustrates a structural schematic of an exemplary testing apparatus; FIG. 5B illustrates a structural block diagram of the exemplary testing apparatus in FIG. 5A; and FIG. 6 illustrates a structural schematic of a die testing region of the exemplary testing apparatus. The automatic die pick-and-place apparatus may be configured in the die testing region of FIGS. 5A-5B and 6.

The automatic die loading region may be configured for wafer loading, die positioning, die stripping and die picking; or automatically pick up the dies from a tape reel, and adapt to wafers of different sizes. The die transporting region may be configured for picking up dies by suction and transporting dies between different test stations. The die testing region may be configured for die position correction, temperature control and testing of different projects. The die testing region may be set up with multiple stations to support multi-station parallel testing or serial testing, and different test projects. The die unloading region may be configured for appearance inspection and unloading to different bins after the die testing is completed, so that dies may be tested and classified into different die bins. In the die automatic loading region, a conventional die loading mechanism may be utilized.

In the die transporting region, an imported high-speed linear motor may be utilized to ensure die transporting speed and stability. The main improvement lies in the suction nozzle transporting mechanism of the die. The suction nozzle transporting mechanism may include six sets of sub-suction-nozzle transporting mechanisms, which may operate in parallel without interfering with each other. Each set of sub-suction-nozzle transporting mechanism may include two suction nozzles which may suck two dies simultaneously. Each set of suction nozzles may be positioned independently to facilitate quick switching between different products. The suction nozzle may support temperature control and be preheated at high temperatures. The specially designed nozzle may avoid contact with the critical regions of the dies and reduce the risk of crushing injuries. The pressure of the suction nozzle to suck the dies may be adjustable to avoid improper suction or crushing of die surfaces. The suction nozzle may be disposed with a vacuum pressure sensor. By adjusting a vacuum pressure value, the adsorption strength of the suction nozzle may be ensured to prevent dies from falling during suction and transporting processes.

Referring to FIG. 6, in the die testing region, two dies on the suction nozzle may place materials (dies) to the calibration platform simultaneously. Two dies may perform position calibration simultaneously to reduce calibration time. Two sets of upper sockets may be installed on a connection board, and each set of sockets may be switched and powered through a signal switch. A high-temperature nitrogen interface may be reserved on the socket of each set. Two sets of lower sockets may be installed on a test carrier, each reserving two sets of temperature control interfaces. The upper and lower sockets may be independent of each other, making position correction and maintenance more convenient. The lower socket may be mounted on a high-speed linear motor and may quickly switch between a loading position and a testing position. A CCD (charge coupled device) may be disposed above a testing site to visually identify whether the die is correctly placed on the testing site. The testing site may be equipped with a vacuum pressure detection system. By determining a pressure value of a sucked die, whether the die is correctly placed on the site and whether there are any abnormalities such as warping may be determined, thereby ensuring that the die is correctly placed on the testing site and preventing warping or flipping.

In the die unloading region, a conventional material (die and/or wafer) unloading mechanism may be applied. An unloading station may be equipped with material (wafer/die) box in-situ detection to prevent unloading failure or abnormality due to that the material box is not empty in the unloading station or the material box is not in a safe position. A large-view CCD may be installed at the unloading station, which may monitor in real time whether an angle and a spacing of the die after being placed in the blue film are abnormal.

### Exemplary Embodiment Three

The present disclosure provides a formation method of above-mentioned automatic die pick-and-place apparatus. FIG. 7 illustrates a flowchart of the formation method of the automatic die pick-and-place apparatus according to various embodiments of the present disclosure. Referring to FIG. 7, the formation method may include following exemplary steps.

At S100, the main body 1 is provided.

At S102, the suction nozzle rod 2 is installed on the main body 1.

At S104, the clamping strip 3 is disposed above the main body 1, where the front end of the clamping strip 3 extends outward from the main body 1 and is clamped to be connected with the upper end of the suction nozzle rod 2.

At S106, the guiding assembly 400 is disposed on the front end surface of the main body 1 and on two sides of the suction nozzle rod 2.

The first spring 41 may be vertically disposed and connected between the clamping strip 3 and the lower portion of the main body 1; the installation groove 5 may be formed on the front end surface of the main body 1; the magnetic block 61 may be inserted in the installation groove 5; the magnetic installation block 62 may be sleeved on the suction nozzle rod 2 and attracted to be connected to the magnetic block 61; and the limiting block 7 may be installed on the front portion of the main body 1; the main body portion 71 of the limiting block 7 may be connected to the main body 1; the limiting portion 72 of the limiting block 7 may be at the outer side of the front end of the main body 1; and the guiding groove 73 for the suction nozzle rod 2 to be inserted may be formed at the surface of the limiting portion 72 facing toward the main body 1.

It may be seen from above-mentioned embodiments that the following beneficial effects may be at least achieved.

When above-mentioned automatic die pick-and-place apparatus is used, the installation groove may be disposed on the front end surface of the main body; the magnetic block may be inserted in the installation groove; the magnetic installation block may be sleeved on the suction nozzle rod and attracted to be connected to the magnetic block; the limiting block may be installed on the front portion of the main body; the main body portion of the limiting block may be connected to the main body; and the limiting portion of the limiting block may be at the outer side of the front end of the main body; and the guiding groove for the suction nozzle rod to be inserted may be formed at the surface of the limiting portion facing toward the main body, which may ensure the freedom of the suction nozzle rod along the vertical direction and facilitate disassembly and assembly of the suction nozzle rod, and may also prevent the suction nozzle rod from falling off due to external force when the suction nozzle rod is wiped.

Above-mentioned embodiments may be only for illustrating technical concepts and features of the present disclosure. The purpose may be to make those skilled in the art understand the content of the present disclosure and implement the present disclosure accordingly and may not limit the protection scope of the present disclosure. All equivalent changes or modifications made based on the spirit and essence of the present disclosure shall be included in the protection scope of the present disclosure.

What is claimed is:

1. An automatic die pick-and-place apparatus, comprising:
a main body;
a suction nozzle rod installed on the main body;
a clamping strip disposed above the main body, wherein a front end of the clamping strip extends outward from the main body and is clamped to be connected with an upper end of the suction nozzle rod; and
a guiding assembly disposed on a front end surface of the main body and on two sides of the suction nozzle rod, wherein:
a first spring is vertically disposed and connected between the clamping strip and a lower portion of the main body;
an installation groove is formed on the front end surface of the main body;
a magnetic block is inserted in the installation groove;
a magnetic installation block is sleeved on the suction nozzle rod and attracted to be connected to the magnetic block; and
a limiting block is installed on a front portion of the main body; a main body portion of the limiting block is connected to the main body; a limiting portion of the limiting block is at an outer side of a front end of the main body; and a guiding groove for the suction nozzle rod to be inserted is formed at a surface of the limiting portion facing toward the main body.

2. The automatic die pick-and-place apparatus according to claim 1, wherein:
the main body portion of the limiting block is connected to a left side surface or a right side surface of the main body through one or more bolts.

3. The automatic die pick-and-place apparatus according to claim 1, wherein:
the limiting block is an L-shaped limiting block.

4. The automatic die pick-and-place apparatus according to claim 1, wherein:
an avoiding opening matched with the magnetic installation block is formed at the limiting portion of the limiting block.

5. The automatic die pick-and-place apparatus according to claim 1, wherein:
the guiding assembly is distributed above and/or below the limiting portion.

6. The automatic die pick-and-place apparatus according to claim 1, wherein:
the installation groove is formed at a central region of the front end surface of the main body.

7. The automatic die pick-and-place apparatus according to claim 1, wherein:
a surface of the magnetic block is coplanar with the front end surface of the main body.

8. The automatic die pick-and-place apparatus according to claim 1, wherein:
the magnetic installation block is fixedly installed at a middle region of the suction nozzle rod.

9. The automatic die pick-and-place apparatus according to claim 1, wherein:
a clamping screw is disposed at the front end of the clamping strip; and an upper end of the first spring is connected to the clamping screw.

10. An automatic die pick-and-place apparatus, comprising:
a main body;
a suction nozzle rod installed on the main body;
a clamping strip disposed above the main body, wherein a front end of the clamping strip extends outward from the main body and is clamped to be connected with an upper end of the suction nozzle rod; and
a guiding assembly, including at least two pairs of bearings and disposed on a front end surface of the main body and on two sides of the suction nozzle rod, wherein:
a first spring is vertically disposed and connected between the clamping strip and a lower portion of the main body;
an installation groove is formed on the front end surface of the main body;
a magnetic block is inserted in the installation groove; and
a magnetic installation block is sleeved on the suction nozzle rod and attracted to be connected to the magnetic block.

11. The automatic die pick-and-place apparatus according to claim 10, further including:
a limiting block installed on a front portion of the main body, wherein a main body portion of the limiting block is connected to the main body; a limiting portion of the limiting block is at an outer side of a front end of the main body; and a guiding groove for the suction nozzle rod to be inserted is formed at a surface of the limiting portion facing toward the main body.

12. The automatic die pick-and-place apparatus according to claim 10, wherein:
the front end surface of the main body includes at least two protruding blocks configured to be spaced apart along a vertical direction.

13. The automatic die pick-and-place apparatus according to claim 12, wherein:
a pair of bearings is installed on a protruding block.

14. The automatic die pick-and-place apparatus according to claim 13, wherein:
in each pair of bearings, a left bearing is installed horizontally on a left side of the protruding block, and a right bearing is installed horizontally on a right side of the protruding block.

15. The automatic die pick-and-place apparatus according to claim 14, wherein:
a clamping channel is formed between the left bearing and the right bearing in each pair of bearings.

16. The automatic die pick-and-place apparatus according to claim 14, wherein:
the suction nozzle rod is in the clamping channel.

17. The automatic die pick-and-place apparatus according to claim 10, wherein:
the guiding assembly is distributed above and/or below the limiting portion.

18. The automatic die pick-and-place apparatus according to claim 10, wherein:
the installation groove is formed at a central region of the front end surface of the main body.

19. The automatic die pick-and-place apparatus according to claim 10, wherein:
a surface of the magnetic block is coplanar with the front end surface of the main body.

20. A formation method of an automatic die pick-and-place apparatus, comprising:
providing a main body;
installing a suction nozzle rod on the main body;
disposing a clamping strip above the main body, wherein a front end of the clamping strip extends outward from the main body and is clamped to be connected with an upper end of the suction nozzle rod; and
disposing a guiding assembly on a front end surface of the main body and on two sides of the suction nozzle rod, wherein:
a first spring is vertically disposed and connected between the clamping strip and a lower portion of the main body;
an installation groove is formed on the front end surface of the main body;
a magnetic block is inserted in the installation groove;
a magnetic installation block is sleeved on the suction nozzle rod and attracted to be connected to the magnetic block; and
a limiting block is installed on a front portion of the main body; a main body portion of the limiting block is connected to the main body; a limiting portion of the limiting block is at an outer side of a front end of the main body; and a guiding groove for the suction nozzle rod to be inserted is formed at a surface of the limiting portion facing toward the main body.
